(19) United States
(12) Patent Application Publication
(10) Pub. No.: US 2024/0281390 A1
(43) Pub. Date: Aug. 22, 2024

(54) MEMORY DEVICE WITH 4N AND 8N DIE STACKS

(71) Applicant: Micron Technology, Inc., Boise, ID (US)

(72) Inventors: Dong Uk Lee, Boise, ID (US); Sujeet Ayyapureddi, Boise, ID (US); Lingming Yang, Meridian, ID (US); Tyler J. Gomm, Boise, ID (US)

(21) Appl. No.: 18/410,808

(22) Filed: Jan. 11, 2024

Related U.S. Application Data
(60) Provisional application No. 63/447,563, filed on Feb. 22, 2023.

(51) Int. Cl. G06F 13/16

(52) U.S. Cl. CPC G06F 13/1678; G06F 13/161; G06F 13/1694

(57) ABSTRACT

A memory device includes a stack of eight memory dies having an 8N architecture and a stack of four memory dies having a 4N architecture. A first half and a second half of the stack of eight memory dies can each include 32 channels divided equally across the first half of dies and across the second half of dies. Banks of each of the 32 channels on the first half of dies can be associated with respective first pseudo channels. Banks of each of the 32 channels on the second half of dies can be associated with respective second pseudo channels. The stack of four memory dies can include the 32 channels divided equally amongst the dies, and the banks of each of the 32 channels on the stack of four memory dies can be divided equally across the respective first and second pseudo channels.

### CROSS-REFERENCE TO RELATED APPLICATION(S)

The present application claims priority to U.S. Provisional Patent Application No. 63/447,563, filed Feb. 22, 2023, the disclosure of which is incorporated herein by reference in its entirety.

### TECHNICAL FIELD

The present disclosure generally relates to memory devices and more particularly relates to a memory device with 4N and 8N die stacks.

### BACKGROUND

New designs for memory devices are being developed to enable faster, less-expensive, or more-reliable computing. For example, new communication technologies can increase the efficiency of communications between memory controllers and the memory devices. Concurrently, designers are implementing additional memory dies in memory devices to increase the memory capacity of these devices. Some methods for increasing the capacity of memory devices, however, may not be compatible with new technologies. As a result, these memory devices can operate inefficiently or inaccurately.

### BRIEF DESCRIPTION OF THE DRAWINGS

FIG. 1 illustrates an example memory device.

FIG. 2 illustrates an example memory device.

FIG. 3 illustrates an example operating environment for a memory device in accordance with an embodiment of the present technology.

FIG. 4 illustrates an example memory die in accordance with an embodiment of the present technology.

FIG. 5 illustrates an example memory device in accordance with an embodiment of the present technology.

FIG. 6 illustrates an example memory device in accordance with an embodiment of the present technology.

FIG. 7 illustrates example control logic for a memory device in accordance with an embodiment of the present technology.

FIG. 8 illustrates example control logic for a memory device in accordance with an embodiment of the present technology.

FIG. 9 illustrates example control logic for a memory device in accordance with an embodiment of the present technology.

FIG. 10 illustrates an example addressing table for a memory device in accordance with an embodiment of the present technology.

### DETAILED DESCRIPTION

Memory devices can be used to implement memory, which stores data to be operated on by a processor. As applications for computing devices become more complex, memory devices are required to store larger amounts of data and communicate that data more quickly. Accordingly, techniques to improve the efficiency and overall capacity of semiconductor devices are needed. One technique to improve the efficiency of semiconductor devices is to develop communication technologies that enable fast and reliable communication of data to and from different components. For example, memory banks can be arranged (e.g., coupled with different buses) such that they can store or return data in a more efficient manner (e.g., communicate with a higher bandwidth). Moreover, the overall capacity of the memory devices can be increased by implementing additional memory dies into the memory device. For example, memory dies can be stacked vertically to increase the number of circuit components in memory device without increasing the device's footprint.

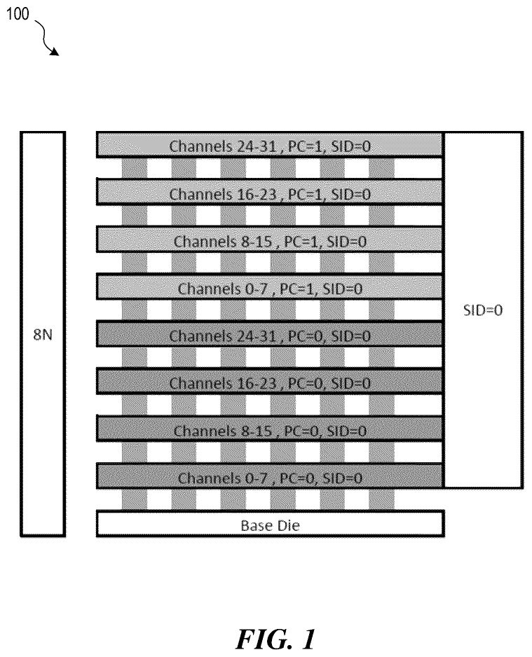

While these techniques individually can be used to increase memory efficiency and capacity, challenges can arise when trying to increase the capacity of devices designed for these improved communication technologies. Take, for example, a high-bandwidth memory (HBM) device, comprised of a stack of multiple memory dies (e.g., DRAM dies). The HBM device may be compliant with an HBM specification (e.g., the HBM3 specification, the HBM4 specification, etc.) and designed to communicate data with an increased bandwidth in comparison to those of other memory devices. An HBM memory device (e.g., an HBM4 memory device) can be designed with 32 channels (e.g., associated with a command and address (CA) bus), where each channel is further subdivided into two pseudo channels (e.g., each associated with a data (DQ) bus). As illustrated in FIG. 1, the HBM memory device can be implemented as eight memory dies stacked vertically onto one another (referred to as a 8H stack), where the eight memory dies are split into two four-die halves. The 32 channels are assigned evenly to the dies of a four-die half (e.g., 8 channels are assigned to each die, for 32 channels total in the four-die half), and the 32 channels are assigned to both four-die halves (i.e., channels 0-31 are assigned to both four-die halves). Each half of the eight-die stack can be associated with a distinct pseudo channel (e.g., the 32 channels distributed over the first half of the stack represent first pseudo channels, and the 32 channels distributed over the second half of the stack represent second pseudo channels). Given that the entire eight-die stack is needed to satisfy the requirements of the HBM specification (e.g., 32 channels further subdivided into two pseudo channels), the eight-die stack can be identified by a single stack identifier (SID). In aspects, this architecture can be referred to as an 8N architecture because the requirements of the HBM specification is satisfied, at minimum, using eight dies. In other words, HBM4 may be referred to as an 8N architecture, as 8 memory dies are needed to form a self-sustaining cube that is compliant with the specification.

The HBM device with an 8N architecture can be symmetrical, such that each of the channels has the same number of banks assigned to each of the two pseudo channels, when implemented as an eight-die device. In fact, symmetrical devices can be created at each multiple of eight dies (e.g., a 16-die HBM device referred to as 16H, 24-die HBM device referred to as 24H, etc.). There exists, however, a need to create HBM devices that do not contain a multiple of eight dies. For example, an HBM device made up of 12 memory dies may be desired (referred to as a 12H stack). HBM devices made up of multiples of 4 memory dies, that are not multiples of 8 (e.g., 20H stack, 28H stack, 36H stack, etc.), may also be desired. If adding an additional stack of four memory dies implemented with the 8N architecture to the HBM device to implement a 12-die device, however, the 32 channels would be distributed evenly across the additional stack of memory dies and associated with a single pseudo channel (e.g., only the first pseudo channel). Given that the first pseudo channel would now include the first half of the eight-die stack as well as the additional stack of four dies, while the second pseudo channel would only implemented at the second half of the eight-die stack, the HBM device would now be asymmetrical (i.e., each pseudo channel would be associated with a different number of banks within the HBM device). Specifically, the device has twice the number of banks associated with the first pseudo channel compared to those associated with the second pseudo channel. This asymmetry can be difficult for a memory controller to handle. For example, the memory controller would have to issue twice as many commands to the banks associated with the first pseudo channel compared to the banks associated with the second pseudo channel, which can be difficult given that the banks of the first and second pseudo channels are coupled with the same CA buses.

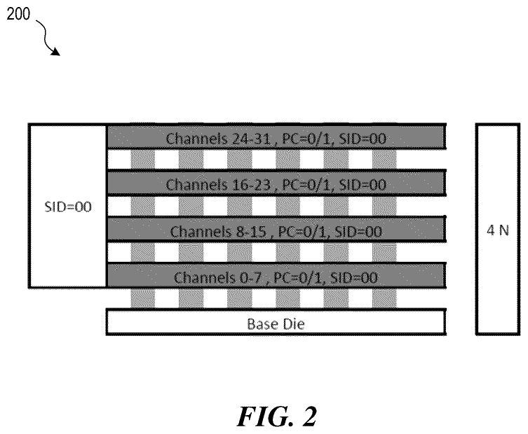

Alternatively, the HBM device can be implemented with a 4N architecture, as illustrated in FIG. 2, such that a four-die stack can satisfy the requirements of the HBM specification. For example, each memory die of the four-die stack can implement both the first and second pseudo channels for each channel (in contrast to the device illustrated in FIG. 1, where each memory die is associated with only a single pseudo channel). The channels can then be distributed evenly over a four-die stack, and banks of each channel can be divided equally between the first and second pseudo channel. To implement a 12-die device, the die stack with a 4N architecture can be implemented three times, with a different SID assigned to each stack. Given that each individual four-die stack of the HBM device is symmetric, the 12-die device implemented with the 4N architecture can be symmetric. There are, however, various shortcomings with implementing a 12H HBM stack using three sets of 4N architected memory dies. During operation, communicating signaling to different die stacks having different SIDs can require additional time. The 4N architecture can impose certain timing constraints (for example, constraints on tCCDR). And there can be a larger power draw on a memory die (e.g., on a DRAM die) using the 4N architecture. Accordingly, an HBM device implemented with a 4N architecture can have decreased bandwidth or increased latency compared to an HBM device implemented with an 8N architecture. Thus, there is need for a symmetric and efficient 12-die HBM device.

To address these needs and others, embodiments of the present disclosure relate to a 12H HBM device (and other HBM devices with multiples of 4 memory devices that are not divisible by 8, such as 20H HBM devices, 28H HBM devices, etc.) with a first stack of eight memory dies having an 8N architecture and a second stack of four memory dies having a 4N architecture. A first half (e.g., four memory dies) of the first stack of eight memory dies can include 32 channels, and the banks of each of the 32 channels on the first half of dies can be associated with respective first pseudo channels of the 32 channels. A second half (e.g., four memory dies) of the first stack of memory dies can include the 32 channels, and the banks of each of the 32 channels on the second half of dies can be associated with respective second pseudo channels of the 32 channels. The second stack of four memory dies can include 32 channels divided equally amongst the four memory dies, and the banks of each of the 32 channels can be divided equally amongst respective first and second pseudo channels of the 32 channels.

In aspects, the first stack of eight memory dies can be associated with a first SID and the second stack of four memory dies can be associated with a second SID. Thus, embodiments of the mixed 4N/8N 12-die memory device disclosed herein can reduce the number of distinct stack identifiers needed to communicate with the memory device compared to the 12-die memory device implemented using three 4N die stacks, which utilized three distinct SIDs. As discussed, commands may be communicated with increased delays when addressing memory dies with different SIDs. Accordingly, reducing the number of SIDs in the memory device can improve the efficiency of communication. Moreover, given that the mixed 4N/8N memory device includes a symmetric four-die 4N die stack and a symmetric eight-die 8N die stack, the combined 12-die memory device can be symmetric with regard to the number of banks associated with the two pseudo channels of each channel, which can reduce communication complexity.

In additional aspects, individual memory dies of the HBM device of the present disclosure can operate according to the 4N architecture or the 8N architecture. That is, for example, the memory die can be configured so that all of the banks of the memory die are associated with a single pseudo channel, or in the alternative the memory die can be configured so that half the banks are associated with a first pseudo channel and the other half of banks are associated with a second pseudo channel. The memory die can be configured to operate according to the 4N or 8N architecture based on the assembly of the HBM device (e.g., by programming a configuration register of the memory device, blowing an electronic fuse of the memory device, etc.).

### Example Operating Environment

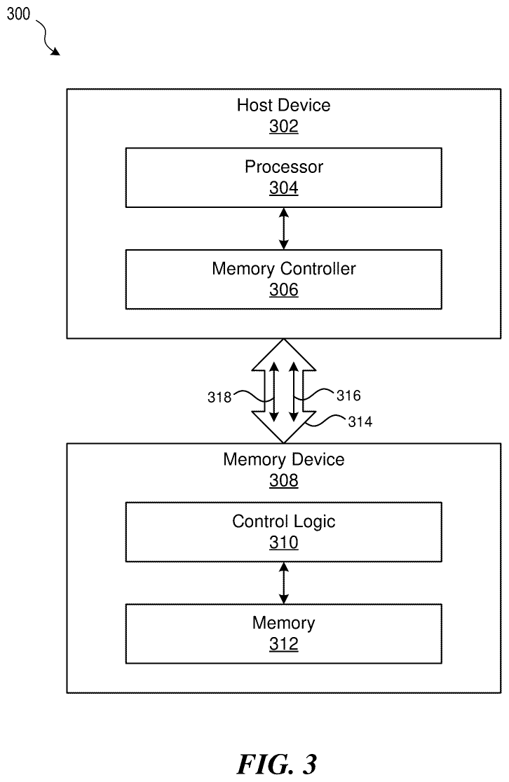

FIG. 3 illustrates an example computing device 300 in which various techniques and devices described in this document can operate. The computing device 300 includes a host device 302, which has at least one processor 304 and at least one memory controller 306, and a memory device 308, which includes control logic 310 and memory 312. In some examples, memory controller 306 may be an aspect of, and may reside on or within, the processor 304. The computer 300 further includes an interconnect 314. The computing device 300 can be any type of computing device, computing equipment, computing system, or electronic device, for example, hand-held devices (e.g., mobile phones, tablets, digital readers, and digital audio players), computers, vehicles, or appliances. Components of the computing device 300 may be housed in a single unit or distributed over multiple, interconnected units (e.g., through wired or wireless interconnects). In aspects, the host device 302 and the memory device 308 are discrete components mounted to and electrically coupled through an interposer (e.g., implementing a portion of the interconnect 314).

As shown, the host device 302 and the memory device 308 are coupled with one another through the interconnect 314. The processor 304 executes instructions that cause the memory controller 306 of the host device 302 to send signals on the interconnect 314 that control operations at the memory device 308. The memory device 308 can similarly communicate data to the host device 302 over the interconnect 314. The interconnect 314 can include one or more CA buses 316 or one or more DQ buses 318. The CA buses 316 can communicate control signaling indicative of commands to be performed at select locations (e.g., addresses) of the memory device 308. The DQ buses 318 can communicate data between the host device 302 and the memory device 308. For example, the DQ buses 318 can be used to communicate data to be stored in the memory device 308 in accordance with a write request, data retrieved from memory device 308 in accordance with a read request, or an acknowledgement returned from the memory device 308 in response to successfully performing operations (e.g., a write operation) at the memory device 308. The CA buses 316 can be realized using a group of wires, and the DQ buses 318 can encompass a different group of wires of the interconnect 314. As some examples, the interconnect 314 can include a front-side bus, a memory bus, an internal bus, peripheral control interface (PCI) bus, etc.

The processor 304 can read from and write to the memory 308 through the memory controller 306. The processor 304 may include the computing device's: host processor, central processing unit (CPU), graphics processing unit (GPU), artificial intelligence (AI) processor (e.g., a neural-network accelerator), or other hardware processor or processing unit.

The memory device 308 can be integrated within the host device 302 or separate from the computing device 300. The memory device 308 can include any memory 312, such as integrated circuit memory, dynamic memory, random-access memory (e.g., dynamic random-access memory (DRAM), static random-access memory (SRAM)), or flash memory to name just a few. The memory device 308 can include memory 312 of a single type or memory 312 of multiple types. In general, the memory device 308 can be implemented as any addressable memory having identifiable locations of physical storage. The memory device 308 can include memory-side control logic 310 that executes commands from the memory controller 306. For example, the control logic 310 can decode signals from the memory controller 306 and perform operations at the memory 312.

As a specific example, the memory device 308 can include a high-bandwidth memory (HBM) device. For example, the memory device 308 can include an interface die implementing at least a portion of the memory-side control logic 310 and one or more memory 312 (e.g., memory dies) stacked to the interface die. The memory-side control logic 310 can receive commands from the memory controller 306 through the interconnect 314 and communicate signaling to execute the commands at the memory 312 in an improved manner compared to other memory devices (e.g., with a higher bandwidth). The interconnect 314 can similarly be implemented in accordance with an HBM device. For example, the interconnect 314 can include 32 channels further divided into two pseudo channels per channel. Each channel can be coupled to a CA bus, and each pseudo channel can transmit or receive data through a respective DQ bus. Thus, the interconnect 314 can include twice as many DQ buses 318 (e.g., 64 DQ buses) as CA buses 316 (e.g., 32 CA buses). Further details of the memory device 308 will be described in greater detail with respect to FIGS. 2 and 3.

### Example Memory Die

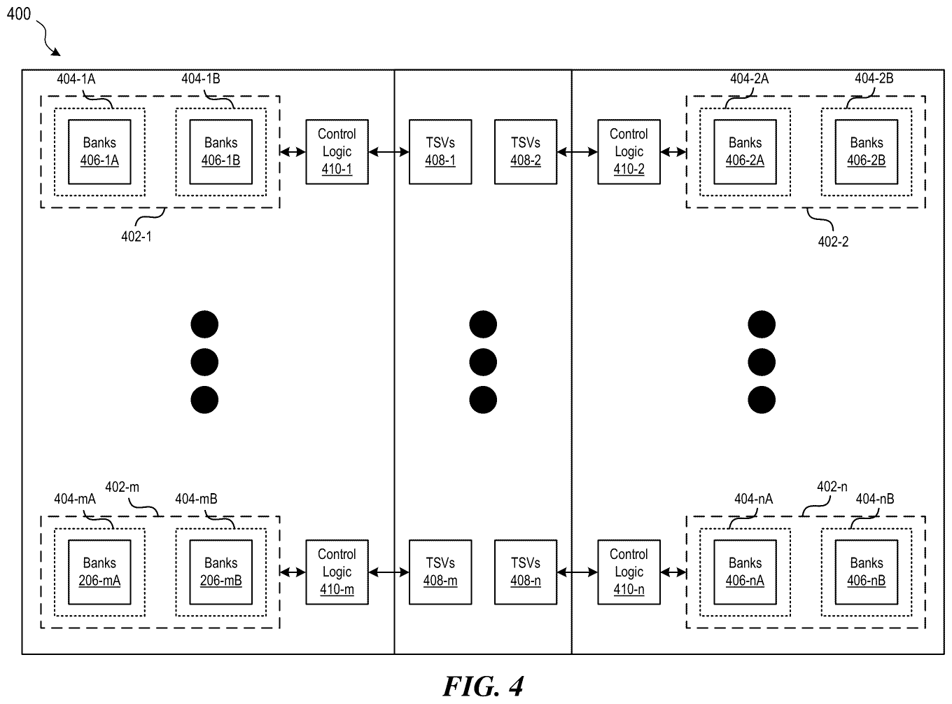

FIG. 4 illustrates an example memory die 400 in accordance with an embodiment of the present technology. In aspects, the memory die 400 can be configured in accordance with a 4N architecture. The memory die 400 includes channels 402 that are further subdivided into pseudo channels 404. The memory die 402 include banks 406 that are organized into the channels 402 and the pseudo channels 404. For example, the channel 402-1 includes a pseudo channel 404-1A and a pseudo channel 404-1B. Banks 406-1A and banks 406-1B are organized into channel 402-1 such that banks 406-1A are within pseudo channel 404-1A and banks 406-1B are within pseudo channel 404-1B. Each of the channels 402 and the pseudo channels 404 couple to through-silicon vias (TSVs) 408, which can implement a CA bus and DQ buses. For example, each of the channels 402 can couple with a corresponding CA bus, and each of the pseudo channels 404 can transmit/receive data to/from a corresponding DQ bus. Thus, banks 406-1A and banks 406-1B of channel 402-1 couple with a CA bus implemented in TSVs 408-1, banks 406-1A of pseudo channel 404-1A transmit/receive data to/from a first DQ bus of the TSVs 408-1, and banks 406-1B of pseudo channel 404-1B transmit/receive data to/from a second DQ bus of the TSVs 408-1.

Control logic 410 (e.g., a portion of the control logic 310 of FIG. 3) can be implemented for each of the channels 402 between the TSVs 408 and the banks 406 to control communication signaling between the banks 406 and the TSVs 408. For example, the control logic 410-1 can be implemented between channel 402-1 and TSVs 408-1. In aspects, the control logic 410-1 can be used to decode and analyze commands transmitted through the CA bus of TSVs 408-1 to initiate the performance of operations (e.g., reads or writes) at the banks 406-1. Similarly, the control logic 410-1 can route return data (e.g., an acknowledgment of a successful operation or data retrieved from the banks 406-1) resulting from performing the operations at the banks 406-1 (e.g., banks 406-1A and banks 406-1B) to the corresponding DQ bus. For example, the control logic 410-1 can route return data resulting from operations at banks 406-1A to the first DQ implemented in TSVs 408-1 and route return data resulting from operations at banks 406-1B to the second DQ implemented in TSVs 408-1.

The memory die 400 can perform operations in accordance with commands received from a memory controller (e.g., memory controller 306 of FIG. 3). For example, the control logic 410-1 can receive a command to implement a read or write operation at the banks 406-1A through the CA bus implemented within the TSVs 408-1. The command can include one or more bits (e.g., in a header) that indicate a targeted rank (e.g., targeted die) and a target pseudo channel (e.g., PC0 or PC1) to which the command is directed. Given that like pseudo channels on corresponding channels of multiple ranks or memory dies return data on the same DQ buses, only a single rank of a same pseudo channel can return data at any one time. Thus, the CA bus implemented within the TSVs 408-1 can couple with multiple ranks or memory dies, and each of the multiple ranks or memory dies can be identified by a stack identifier (SID) (e.g., “0”, “1”, and so on). The control logic 410-1 can receive command transmitted over the CA bus to which it is coupled and determine if the command includes the SID associated with the memory die 400 (e.g., or rank in which memory die 400 is implemented). If so, the control logic 410-1 can decode the command and transmit signals to targeted banks of the channel 402-1. If not, the command can be ignored by the control logic 410-1.

Once the command is determined to be directed to the memory die 400, the command can be analyzed to determine which of the banks 406-1 are targeted by the command. The command can include one or more bits (e.g., in a header) indicating to which of the pseudo channels 404 the command is directed. For example, the command could indicate a single pseudo channel bit with value “1” when the command is directed to pseudo channel 404-1A (e.g., or one or more of banks 406-1A) and a single pseudo channel bit with value “0” when the command is directed to pseudo channel 404-1B (e.g., or one or more of banks 406-1B). The control circuitry 410-1 can analyze the command and determine, based on the one or more bits identifying the targeted banks, to which of the banks 406-1 to transmit signaling to perform the operations indicated by the command. In aspects, the control logic 410-1 can determine the banks 406-1A of pseudo channel 404-1A to be the targeted banks. Accordingly, the control logic 410-1 can decode the command to determine a targeted row, a targeted column, and a desired operation associated with the command. The control logic 410-1 can then forward signaling to the banks 406-1A to perform the desired operation at the targeted row and column of the banks 406-1A.

Performing operations at the banks 406-1A can cause data to be returned to the control logic 410-1 for output to the memory controller. For example, if the operation is a read operation, the return data can include data stored in the targeted row and column of the banks 406-1. Alternatively, if the operations is a write operation, the data can include an acknowledgement (e.g., a success flag or a return of the data that was written) of a successful write operation at the targeted row and column of the banks 406-1A. Given that the banks 406-1A and the banks 406-1B are configured to return data on different DQ buses implemented within the TSVs 408-1, the control logic 410-1 can determine which DQ bus to route the return data to. For example, return data resulting from operations at the banks 406-1A can be routed to the first DQ bus of the TSVs 408-1, and return data resulting from operations at the banks 406-1B can be routed to the second DQ bus of the TSVs 408-1. In aspects, the control logic 410-1 determines where the return data is originating from by analyzing a header of the return data or based on the previous decision regarding where to route the command from the CA bus. Once routed to the associated DQ bus of the TSVs 408-1, the return data can be transmitted to the memory controller using the associated DQ bus.

In aspects, the internal data path from the banks 406-1A to the control logic 410-1, or vice versa, can be at least partially shared with the internal data path from the banks 406-1B to the control logic 410-1, or vice versa. Thus, data contention can occur when operations at the banks 406-1 cause data to be returned from the banks 406-1A and the banks 406-1B at the same time. Accordingly, it is important to mitigate concurrent returns from two pseudo channels of a same channel on a single die. In other aspects, in which banks 406-1 are associated with different pseudo channels, the banks do not receive commands at the same time (causing data contention) because they share a common command bus. In still other, the banks 406-1A and the banks 406-1B can each be connected to the TSVs 408-1 through independent data paths. In this case, the return data can be routed to the associated DQ buses of the TSVs 408-1 directly through the independent data paths.

Channel 402-2, channel 402-m, and channel 402-n can be similarly configured, where “m” and “n” are positive integers. For example, Channel 402-2 can include pseudo channels 404-2 (e.g., pseudo channel 404-2A having banks 406-2A and pseudo channel 404-2B having banks 406-2B) coupled with TSVs 408-2 through control logic 410-2. Channel 402-m and channel 402-n can be similarly arranged with pseudo channels 404-m (e.g., pseudo channel 404-mA having banks 406-mA and pseudo channel 404-mB having banks 406-mB) and pseudo channels 406-n (e.g., pseudo channel 404-nA having banks 406-nA and pseudo channel 404-nB having banks 406-nB) coupled with TSVs 408-m and TSVs 408-n through control logic 410-m and control logic 410-n, respectively. There can be any number of channels 402 on the memory die 400. As a specific example, n can be 8 such that the memory die 400 includes channel 402-1 through channel 402-8. In this way, each rank can include 4 memory dies having 8 channels each, thus implementing 32 channels per rank, as required by the HBM specification.

Although illustrated as a single component of control logic, the control logic 410 associated with the various channels 402 can be implemented as discrete portions of control logic. For example, the control logic 410 can be implemented at any location on or off the memory die 400 (e.g., at an interface die of the memory device). In aspects, portions of the control logic 410 can be implemented at different locations. For example, a portion of the control logic 410 responsible for decoding the command or determining the targeted banks/dies can be separate from a portion of the control logic 410 responsible for routing the return data to an associated DQ bus. Accordingly, it should be appreciated that the control logic 410 is shown schematically in FIG. 4 as a single component associated with each of the channels 402 for ease of description only.

In aspects, a memory die configured in accordance with an 8N architecture can look similar to the memory die 400 illustrated in FIG. 4 but without the channels 402 being subdivided into multiple pseudo channels 404. For example, with reference to FIG. 4, a memory die configured in accordance with an 8N architecture can include banks 406-1 of the channel 402-1 associated solely with the first pseudo channel 404-1A, or the second pseudo channel 404-1B, but not both. Others of the channels 402 can be similarly configured. In this way, each of the pseudo channels 404 of a memory die configured in accordance with an 8N architecture can include twice the number of banks (e.g., pseudo channel 404-1A includes banks 406-1A as well as 406-1B) as compared to a memory die configured in accordance with a 4N architecture. In some embodiments of memory dies configured in accordance with an 8N architecture, the control logic 410 does not include circuitry to determine to which DQ bus to route return data, given that only a single pseudo channel 404 is present on a single die for each of the channels 402. In some embodiments of memory dies configured in accordance with an 8N architecture, the control logic 410 does include circuitry to determine to which DQ bus to route return data.

### Example Memory Device

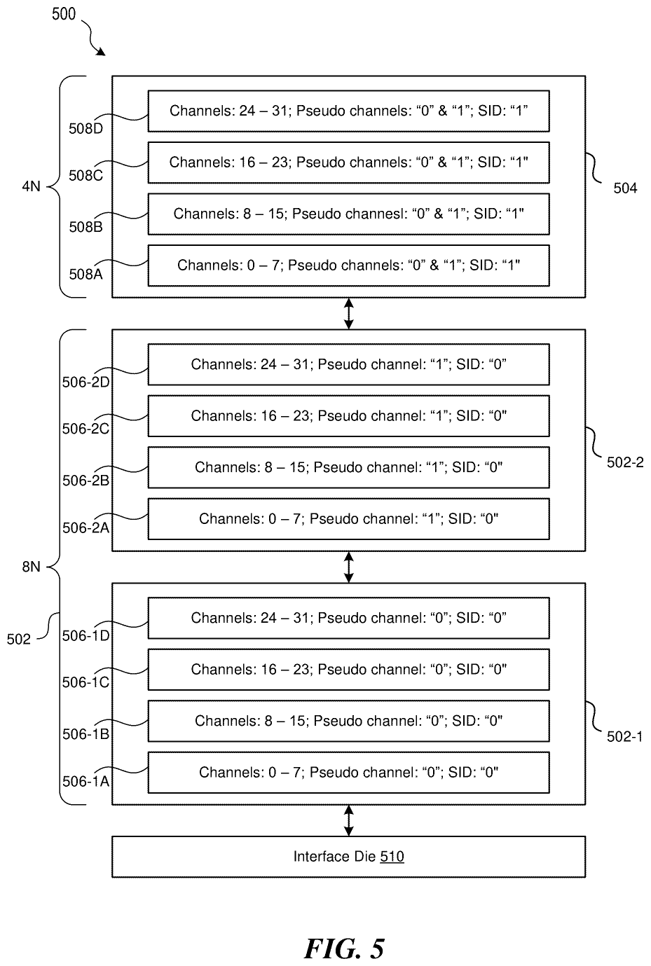

FIG. 5 illustrates an example memory device 500 in accordance with an embodiment of the present technology. As illustrated, the memory device 500 include an 8N stack of memory dies 502, made up of a first half of the 8N stack of memory dies 502-1 and a second half of the 8N stack of memory dies 502-2. The memory device 500 additionally includes a 4N stack of memory dies 504. The first half of the 8N stack of memory dies 502-1 can include memory dies 506-1 (e.g., 506-1A through 506-1D). Each of the memory dies 506-1 can include eight distinct channels such that the memory dies 506-1 collectively include 32 channels. Banks of the eight channels on the memory dies 506-1 can be associated with a first pseudo channel having identifier “0”. The second half of the 8N stack of memory dies 502-2 can include memory dies 506-2 (e.g., 506-2A through 506-2D). Each of the memory dies 506-2 can include eight distinct channels such that the memory dies 506-2 collectively include 32 channels. Banks of the 32 channels on the memory dies 506-2 can be associated with a second pseudo channel having identifier “1”. The first half of the 8N stack of memory dies 502-1 and the second half of the 8N stack of memory dies 502-2 can each be associated with the same SID of “0”.

The 4N stack of memory dies 504 can include memory dies 508 (e.g., 508A-508D). The memory dies 508 can include 32 channels distributed equally across the memory dies 508 such that each of the memory dies 508 includes eight channels. Banks of the 32 channels on the memory dies 508 can be divided equally amongst the first and second pseudo channel. The 4N stack of memory dies 504 can have an SID, “1”, different from the 8N stack of memory dies 502.

The memory device 500 can further include an interface die 510 in accordance with the HBM specification. The interface die 510 can optimize signaling to/from the memory dies of the memory device 500.

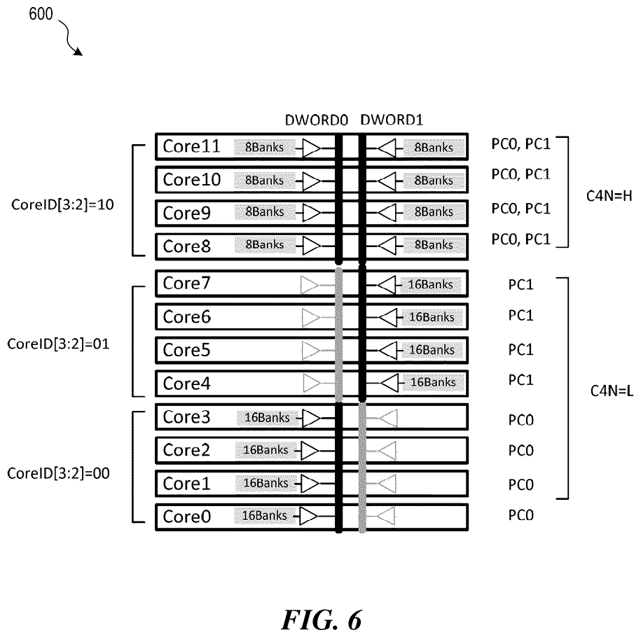

FIG. 6 illustrates an example memory device 600 in accordance with an embodiment of the present technology. The example memory device 600 illustrate a 12H stack formed from 12 memories dies, identified as Core0 through Core 11. For example, Core 0 through Core 7 can implement an 8N stack of memory dies, and Core 8 through Core 11 can implement a 4N stack of memory dies. The various memory cores can be identified through core identifiers (CoreID). As described herein, the CoreID represents a physical ID for each memory die in the HBM device. Four bits can be used implement 12 distinct CoreIDs. For example, Core 0 through Core 3 can each have most-significant bits (e.g., CoreID[3:2]) equal to “00”, Core 4 through 7 can each have most-significant bits equal to “01”, and Core 8 through 11 can have most-significant bits equal to “10”.

The memory device 600 can also include circuitry (e.g., a fuse, a mode register, a selector) to indicate the configuration of the cores. For example, each of the cores can include a mode register (C4N) or other circuitry that indicates whether the core is configured in accordance with a 4N architecture or an 8N architecture. As illustrated, Core 8 through Core 11 have C4N set to HIGH, thus indicating a 4N architecture, and Core 0 through Core 7 have C4N set to LOW, thus indicating an architecture other than 4N (e.g., 8N).

The memory device 600 also includes DQ buses, DWORD0 and DWORD1, associated with each of the respective first and second pseudo channels of each channel. For example, DWORD0 can be multiple DQ buses used to return data from respective first pseudo channels of each channel (e.g., a pseudo channel identified as PC0), and DWORD1 can be multiple DQ buses used to return data from respective second pseudo channels of each channel (e.g., a pseudo channel identified as PC1). As illustrated, Core 0 through Core 3 each include 16 banks returning data on DWORD0, and Core 4 through Core 7 each include 16 banks returning data on DWORD1. Core 8 through 11 is configured in a 4N architecture. Core 8 through Core 11 each include 16 banks divided equally amongst first and second pseudo channels. Eight banks of each of Core 8 through Core 11 return data on DWORD0, and 8 banks of each of Core 8 through 11 return data on DWORD1. Thus, in this example, each pseudo channel includes 24 banks. In general, Core 8 through Core 11 include half as many banks on each pseudo channel as Core 0 through Core 7.

Given that Core 8 through Core 11 include half as many banks on each pseudo channel as Core 0 through 7, the number of bank addressing (BA) bits used to address banks of the pseudo channels of Core 8 through Core 11 can be less than the number of BA bits used to address banks of the pseudo channels of Core 0 through Core 7. For example, four bank addressing bits (e.g., BA[0:3]) can be used to address the 16 banks per pseudo channel of Core 0 through Core 7, and three bank addressing bits (e.g., BA[0:2]) can be used to address the 8 banks per pseudo channel of Core 0 through Core 7. If the same number of bits are used to address the banks of Core 0 through Core 7 and Core 8 through Core 11, the most-significant bit (BA[3]) can equal “0”.

### Example Control Logic for a Memory Device

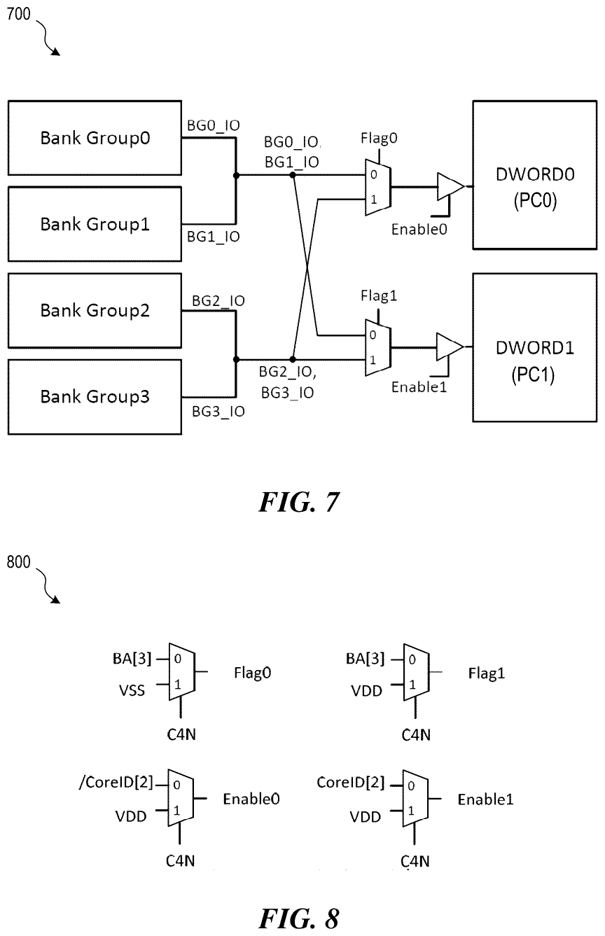

FIG. 7 illustrates example control logic 700 for a memory die of a memory device in accordance with an embodiment of the present technology. In aspects, the control logic 700 can control how data from banks on the memory die (identified as Bank Groups 0 through 3) can be routed to a DQ bus associated with a pseudo channel (e.g., the DQ bus identified as DWORD0 can be associated with the pseudo channel identified as PC0, and the DQ bus identified as DWORD1 can be associated with the pseudo channel identified as PC1). For example, when the memory die is configured in accordance with the 4N architecture, data from some bank groups may be routed to the DQ bus associated with one pseudo channel (e.g., Bank Groups 0 and 1 routed to DWORD0), and data from other bank groups may be routed to the DQ bus associated with another pseudo channel (e.g., Bank Groups 2 and 3 routed to DWORD1). As a further example, when the memory die is not configured in accordance with the 4N architecture (e.g., it is configured in accordance with the 8N architecture), data from all of the bank groups may be routed to the same DQ bus. In other implementations, the data from all of the bank groups may be directly routed to the same DQ bus without the control logic 700 when the memory die that is configured in accordance with the 4N architecture. The data can be output to an associated DQ bus based on inputs (e.g., Flag0, Flag1, Enable0, Enable1) to multiplexers (MUXs) and other circuitry, as illustrated in FIG. 7.

FIG. 8 illustrates example control logic 800 for a memory device in accordance with an embodiment of the present technology. Specifically, the control logic 800 illustrates logic to determine inputs to the MUXs and other circuitry of the control logic 700 illustrated in FIG. 7. For example, the inputs can be determined based on the bank address (e.g., BA) of a targeted bank, the CoreID of the targeted die, or the configuration of the targeted die (e.g., C4N). When a memory die is configured to operate in accordance with the 4N architecture (e.g., C4N is asserted), the control logic 800 can set one or more signals so that (in combination with the control logic 700) the memory die sends data from some bank groups to a first pseudo channel and data from other bank groups to a second pseudo channel. For example, with C4N asserted the control logic 800 sets the signal Flag0 to 0 (e.g., VSS), so that Bank Groups 0 and 1 are driven onto DWORD0 (e.g., associated with a first pseudo channel), and sets the signal Flag1 to 1 (e.g., VDD), so that Bank Groups 2 and 3 are driven onto DWORD1 (e.g., associated with a second pseudo channel). In contrast, when the memory die is configured in accordance with the 8N architecture (e.g., C4N is de-asserted), the control logic 800 can set one or more signals so that (in combination with the control logic 700) the memory die sends data from a selected bank on to the DQ bus associated with the first or second pseudo channel based on where the memory die is located in the stack (based on CoreID[2]). For example, with C4N de-asserted the control logic enables data on DWORD0 (associated with a first pseudo channel) when CoreID[2] is de-asserted, and enables data on DWORD1 (associated with a second pseudo channel) when CoreID[2] is asserted; the bank to be driven depends on the bank address (e.g., BA[3]).

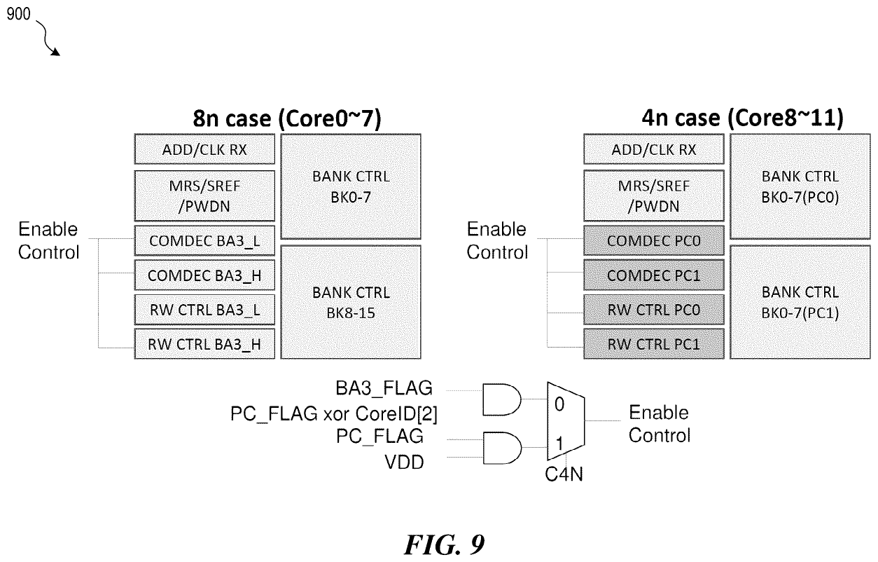

FIG. 9 illustrates example control logic 900 for a memory device in accordance with an embodiment of the present technology. For example, a die can be determined as the targeted die based on the Enable Control input, which can be determined from the bank address (BA) (e.g., a most-significant BA bit), the targeted pseudo channel (PC_FLAG), the CoreID, and the configuration of a targeted die (C4N). Once a die is determined to be the targeted die, the command can be decoded based on the control logic 900. For example, in an 8N architecture, the signaling used to perform an operation associated with the command can routed to bank 0 through bank 7 or bank 8 through bank 15 based on the most-significant BA bit (BA[3]). In a 4N architecture, the signaling used to perform an operation associated with the command can routed to bank 0 through bank 7 of a first pseudo channel (PC0) or bank 0 through bank 7 of a second pseudo channel (PC1) based on the bits indicating the targeted pseudo channel. Thus, read or write operations can be performed at the targeted banks based on the command.

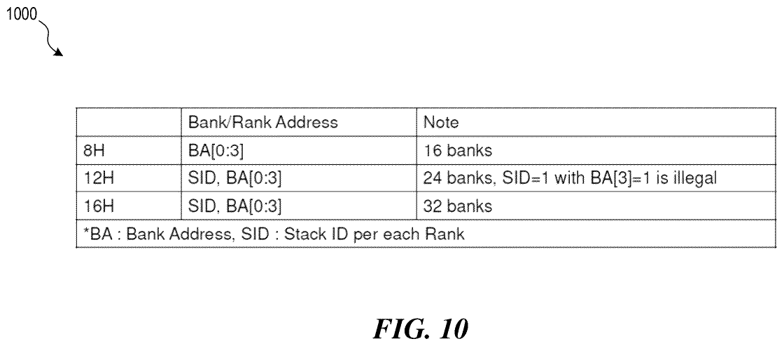

FIG. 10 illustrates an example addressing table 1000 for a memory device in accordance with an embodiment of the present technology. Specifically, the addressing table 1000 illustrates example addressing for an eight-die stack (e.g., a single 8N die stack), a 12-die stack (e.g., an 8N die stack and a 4N die stack), and a 16-die stack (e.g., two 8N die stacks). As illustrated, each pseudo channel of the eight-die stack can include 16 banks. Thus, the eight-die stack can be addressed using four BA bits. Given that only a single 8N die stack is implemented, SIDs are not needed to differentiate multiple stacks.

For a 12-die stack, an SID bit and four BA bits can be used to address the 24 banks of each pseudo channel. The SID can be used to distinguish between the 8N die stack and the 4N die stack, and the BA bits can be used to address specific banks within the channels of the die stacks. Given that the 4N die stack includes half as many banks (e.g., 8 banks) per pseudo channel as the 8N die stack (e.g., 16 banks), one less bit can be used to address the banks of the 4N die stack. Thus, when the 4N die stack is targeted (e.g., SID=“1”), the most-significant BA bit can be set to “0” (e.g., BA[3]=“0”).

For a 16-die stack, two 8N die stacks can be implemented. Thus, the addressing can be the same as the eight-die stack with the addition of an SID bit to distinguish between the two 8N stacks.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

1. A memory device, comprising:
32 command address buses associated with 32 channels;
32 first DQ buses associated with respective first pseudo channels of the 32 channels;
32 second DQ buses associated with respective second pseudo channels of the 32 channels;
a stack of eight memory dies comprising:
four first memory dies collectively having 32 first sets of banks each coupled respectively with the 32 command address buses and each configured to return data on a respective first DQ bus of the 32 first DQ buses; and
four second memory dies collectively having 32 second set of banks each coupled respectively with the 32 command address buses and each configured to return data on a respective second DQ bus of the 32 second DQ buses; and
a stack of four memory dies coupled with the stack of eight memory dies, the stack of four memory dies comprising four third memory dies collectively having:
32 third sets of banks each coupled respectively with the 32 command address buses and each configured to return data on a respective first DQ bus of the 32 first DQ buses; and
32 fourth sets of banks each coupled respectively with the 32 command address buses and each configured to return data on a respective second DQ bus of the 32 second DQ buses,
wherein at least one of the third sets of banks and at least one of the fourth sets of banks are located on a same memory die of the four third memory dies.

2. The memory device of claim 1, wherein each of the third sets of banks and the fourth sets of banks comprise half as many banks as each of the first sets of banks and the second sets of banks.

3. The memory device of claim 1, wherein the memory device comprises a high-bandwidth memory (HBM) device.

4. The memory device of claim 1, wherein the stack of eight memory dies is associated with a first stack identifier and the stack of four memory dies is associated with a second stack identifier.

5. A high-bandwidth memory (HBM) device comprising:
a plurality of first memory dies configured in accordance with an 8N architecture; and
a plurality of second memory dies configured in accordance with a 4N architecture, and
wherein at least one of the first memory dies or the second memory dies is configurable to operate in accordance with the 8N architecture and the 4N architecture.

6. The HBM device of claim 5, wherein the plurality of first memory dies are associated with a first stack identifier and the plurality of second memory dies are associated with a second stack identifier.

7. The HBM device of claim 5, wherein the at least one of the first memory dies or the second memory dies comprises control logic configured to configure the at least one of the first memory dies or the second memory dies to operate in accordance with the 8N architecture in a first configuration and in accordance with the 4N architecture in a second configuration.

8. The HBM device of claim 7, wherein:
the control logic comprises one or more multiplexers; and
the control logic is configurable between the first configuration and the second configuration based on inputs to the one or more multiplexers.

9. The HBM device of claim 8, wherein at least one of the inputs to the one or more multiplexers comprises a most significant bit of a bank address of an addressed bank of the first memory dies or the second memory dies.

10. The HBM device of claim 8, wherein at least one of the inputs to the one or more multiplexers comprises a bit of a stack identifier associated with the at least one of the plurality of first memory dies or at least one of the plurality of second memory dies.

11. The memory device of claim 1, wherein the same memory die of the four third memory dies on which the at least one of the third set of banks and the at least one of the fourth set of banks are located further comprises:
a data path configured to provide data from the at least one of the third set of banks and the at least one of the fourth set of banks to the at least one respective first DQ bus of the 32 DQ buses and the at least one respective second DQ bus of the 32 DQ buses,
wherein the data path comprises control logic configured to:
when in a first configuration, direct data from the at least one of the third set of banks to the at least one respective first DQ bus of the 32 DQ buses and direct data from the at least one of the fourth set of banks to the at least one respective second DQ bus of the 32 DQ buses, and
when in a second configuration, direct both data from the at least one of the third set of banks and data from the at least one of the fourth set of banks to the at least one respective first DQ bus of the 32 DQ buses or to the at least one respective second DQ bus of the 32 DQ buses.

12. The memory device of claim 11, wherein:
the control logic comprises one or more multiplexers; and
the control logic is configurable between the first configuration and the second configuration based on inputs to the one or more multiplexers.

13. The memory device of claim 12, wherein at least one of the inputs to the one or more multiplexers comprises a most significant bit of a bank address of an addressed bank of the at least one of the third set of banks or the at least one of the fourth set of banks.

14. The memory device of claim 12, wherein at least one of the inputs to the one or more multiplexers comprises a bit of a stack identifier associated with the stack of four memory dies.

15. The memory device of claim 1, further comprising an interface die configured to transmit signaling to and receive signaling from the stack of four memory dies and the stack of eight memory dies.

16. A method comprising:
transmitting, from an interface die of a high-bandwidth memory (HBM) device, to a first memory bank on a memory die of the HBM device, and using a first command address bus, signaling that causes the first memory bank to return first data on a first DQ bus;
in response to transmitting the signaling that causes the first memory bank to return the first data on the first DQ bus, receiving, at the interface die and using the first DQ bus, the first data;
transmitting, from the interface die of the HBM device, to a second memory bank on the memory die of the HBM device, and using the first command address bus, signaling that causes the second memory bank to return second data on a second DQ bus,
wherein the second memory bank is different from the first memory bank and the second DQ bus is different from the first DQ bus; and
in response to transmitting the signaling that causes the second memory bank to return the second data on the second DQ bus, receiving, at the interface die and using the second DQ bus, the second data.

17. The method of claim 16, comprising:
transmitting, from the interface die of the HBM device, to a third memory bank on a second memory die of the HBM device, and using the first command address bus, signaling that causes the third memory bank to return third data on the first DQ bus;
in response to transmitting the signaling that causes the third memory bank to return the third data on the first DQ bus, receiving, at the interface die and using the first DQ bus, the third data;
transmitting, from the interface die of the HBM device, to a fourth memory bank on the second memory die of the HBM device, and using the first command address bus, signaling that causes the fourth memory bank to return fourth data on the first DQ bus,
wherein the fourth memory bank is different from the third memory bank; and
in response to transmitting the signaling that causes the fourth memory bank to return the fourth data on the first DQ bus, receiving, at the interface die and using the first DQ bus, the fourth data.

18. The method of claim 17, comprising:
transmitting, from the interface die of the HBM device, to a fifth memory bank on a third memory die of the HBM device, and using the first command address bus, signaling that causes the fifth memory bank to return fifth data on the second DQ bus;
in response to transmitting the signaling that causes the fifth memory bank to return the fifth data on the second DQ bus, receiving, at the interface die and using the second DQ bus, the fifth data;
transmitting, from the interface die of the HBM device, to a sixth memory bank on the third memory die of the HBM device, and using the first command address bus, signaling that causes the sixth memory bank to return sixth data on the second DQ bus,
wherein the fifth memory bank is different from the sixth memory bank; and
in response to transmitting the signaling that causes the sixth memory bank to return the sixth data on the second DQ bus, receiving, at the interface die and using the second DQ bus, the sixth data.

19. The method of claim 18, wherein:
the first memory die is configured in accordance with a 4N architecture; and
the second memory die and the third memory die are configured in accordance with an 8N architecture.

20. The method of claim 18, wherein:
transmitting the signaling that causes the first memory bank to return the first data on the first DQ bus comprises identifying the first memory die by at least a first stack identifier;
transmitting the signaling that causes the third memory bank to return the third data on the first DQ bus comprises identifying the second memory die at least by a second stack identifier different from the first stack identifier; and
transmitting the signaling that causes the fourth memory bank to return the fourth data on the second DQ bus comprises identifying the third memory die by at least the second stack identifier.
